(19) United States
(12) Patent Application Publication
(10) Pub. No.: US 2024/0413122 A1
(43) Pub. Date: Dec. 12, 2024

(54) APPARATUS AND MEMORY DEVICE INCLUDING SPIRAL TSV CONNECTION

(71) Applicant: MICRON TECHNOLOGY, INC., BOISE, ID (US)

(72) Inventors: WATARU NOBEHARA, Sagamihara (JP); HARUNOBU KONDO, Sagamihara (JP)

(73) Assignee: MICRON TECHNOLOGY, INC., Boise, ID (US)

(21) Appl. No.: 18/659,173

(22) Filed: May 9, 2024

Related U.S. Application Data
(60) Provisional application No. 63/506,421, filed on Jun. 6, 2023.

(51) Int. Cl. H01L 25/065; H01L 23/498; H01L 23/528; H01L 25/18; H10B 80/00

(52) U.S. Cl. CPC H01L 25/0657; H01L 23/49827; H01L 23/5283; H01L 25/18; H10B 80/00; H01L 2225/06541

(57) ABSTRACT

According to one or more embodiments of the disclosure, an apparatus comprises a plurality of core chips that includes a plurality of spiral through-substrate vias (TSVs). The core chips are stacked with one another in a face-to-face manner to define a common channel in first and second core chips, which face each other, of the plurality of core chips. The first core chip and the second core chips include a first function circuit and a second function circuit coupled to the first function circuit, respectively. The first function circuit and the second function circuit provide the same functions.

### CROSS REFERENCE TO RELATED APPLICATION(S)

This application claims priority to U.S. Provisional Application No. 63/506,421, filed Jun. 6, 2023. The aforementioned application is incorporated herein by reference, in its entirety, for any purpose.

### BACKGROUND

High data reliability, high speed of memory access, lower power consumption, and reduced chip size are features that are demanded from semiconductor memory. Some three-dimensional (3D) memory devices may be formed by stacking memory chips (or memory dies) vertically and interconnecting the stacked memory chips using through-substrate (or through-silicon) vias (TSVs). Benefits of the 3D memory devices include shorter interconnects which reduce signal delays and power consumption, a larger number of vertical vias between layers which allow wide bandwidth buses between functional blocks in different layers, and a considerably smaller footprint. Thus, the 3D memory devices contribute to higher memory access speed, lower power consumption, and chip size reduction. Example 3D memory devices include a High Bandwidth Memory (HBM) and a Hybrid Memory Cube (HMC). The HBM is a type of memory including a high-performance dynamic random access memory (DRAM) interface chip and vertically stacked DRAM chips.

### BRIEF DESCRIPTION OF THE DRAWINGS

FIG. 1A is a schematic illustration of at least part of an apparatus including a plurality of core chips CCs and an IF chip with a plurality of TSVs according to an embodiment of the disclosure.

FIG. 1B is a schematic illustration of part of a channel layout of core chip layers according to an embodiment of the disclosure.

FIG. 1C is a schematic illustration of part of core chip layers in a cross-sectional view according to an embodiment of the disclosure.

FIG. 1D is a schematic illustration of part of core chip layers in a cross-sectional view according to an embodiment of the disclosure.

FIG. 2A is a schematic illustration of at least part of an apparatus including a plurality of core chips CCs and an IF chip with a plurality of TSVs according to an embodiment of the disclosure.

FIG. 2B is a schematic illustration of part of a channel layout of core chip layers according to an embodiment of the disclosure.

FIG. 2C is a schematic illustration of part of core chip layers in a cross-sectional view according to an embodiment of the disclosure.

FIG. 2D is a schematic illustration of part of core chip layers in a cross-sectional view according to an embodiment of the disclosure.

FIG. 3A is a schematic illustration of at least part of an apparatus 300 including a plurality of core chips CCs and an IF chip with a plurality of TSVs according to an embodiment of the disclosure.

FIG. 3B is a schematic illustration of part of a channel layout of core chip layers according to an embodiment of the disclosure.

FIG. 4 is a schematic diagram of an apparatus including a memory device and a processor according to an embodiment of the disclosure.

### DETAILED DESCRIPTION

Various example embodiments of the disclosure will be described below in detail with reference to the accompanying drawings. The following detailed descriptions refer to the accompanying drawings that show, by way of illustration, specific aspects in which embodiments of the disclosure may be practiced. These embodiments are described in sufficient detail to enable those skilled in the art to practice the disclosure. Other embodiments may be utilized, and structure, logical and electrical changes may be made without departing from the scope of the disclosure. The various embodiments disclosed herein are not necessary mutually exclusive, as some disclosed embodiments can be combined with one or more other disclosed embodiments to form new embodiments.

In the descriptions, common or related elements and elements that are substantially the same are denoted with the same signs, and the descriptions thereof may be reduced or omitted. In the drawings, the dimensions and dimensional ratios of each unit do not necessarily match the actual dimensions and dimensional ratios in the embodiments.

According to some embodiments of the disclosure, a semiconductor device, such as a memory device, and another semiconductor device, such as a processor, may be provided on a packaging substrate. In some embodiments, a memory device may be a dynamic random access memory (DRAM), a High Bandwidth Memory (HBM), or a Hybrid Memory Cube (HMC). In some embodiments, a processor may be a central processor, a graphical processor, a memory controller, or the like. In some embodiments, an interposer IP may be provided between the semiconductor devices and the packaging substrate. The semiconductor devices may be coupled to the interposer IP by external terminals, such as bumps or microbumps. The external terminals may form electrodes between the semiconductor devices and the interposer IP. The interposer IP may be stacked on and coupled to the packaging substrate by, for example, solder balls.

According to some embodiments of the disclosure, a semiconductor device may have a layered structure in which a plurality of core chips CCs (or core dies) are stacked with one another on an interface (IF) chip (or an IF die). The IF chip may be coupled to an interposer IP via external terminals. In some embodiments, the core chips CCs and the IF chip may be semiconductor chips each including semiconductor substrates, such as silicon (Si) substrates, and further including circuits, such as a command circuit, a control circuit and a buffer circuit. In some embodiments, each single chip may also be referred to as a semiconductor device, and a plurality of chips form a layered or stacked structure of multiple semiconductor devices. In some embodiments, each of the core chips CCs includes a plurality of wiring layers, such as metal layers, provided by for example a back-end-of-line (BEOL) process and/or a middle-of-line (MOL) process, on the semiconductor substrate. The wiring layers may be stacked and connected with one another via, for example, conductive contacts. In some embodiments, the core chips CCs may be provided in a face-up manner wherein an uppermost wiring layer among the wiring layers of each chip faces upwards. The face-up manner may also be referred to as a forward direction manner or simply a forward direction. In some embodiments, the core chips CCs may be provided in a face-down manner wherein an uppermost wiring layer among the wiring layers of each chip face downwards. The face-down manner may also be referred to as a reverse direction manner or simply a reverse direction.

In a case of a memory device, the plurality of core chips CCs may include a plurality of memory chips (or memory dies) stacked on the IF chip. The number of the plurality of memory chips may be four or eight, but is not limited thereto. Each of the memory chips may include a memory array for storing data and further include circuits for performing memory operations, such as read and write operations. Each memory chip may include one single channel or a plurality of channels. In some embodiments, a channel may be a circuit block operable as a single memory device. In some embodiments, a channel may represent a separable addressable memory space that may be accessed to read data from the channel and to write data to the channel. Channels may be referred to or denoted as Channels A, B, C, D, E, F, G, H, and so on. Each chip/die may include a command circuit for each channel. A command signal may be independently assigned and transmitted for each channel. The command signal may include a control signal, a clock signal, and a data signal.

In some embodiments, the plurality of core chips CCs and the IF chip may be coupled to one another by a plurality of conductive vias. The IF chip may provide a plurality of interfaces which provide signals to and/or receive signals from the core chips CCs or channels of the core chips CCs. The signals may be external signals transmitted by the IF chip. The conductive vias may provide input/output lines (IOs) between the channels of the core chips CCs and the IF chip. At each chip, internal signals may also be provided to and from the corresponding channel by the conductive vias and other conductive lines, such as wirings and terminals, provided to the chip. The conductive vias may be through-substrate or through-silicon vias (TSVs). The TSVs may be provided to the core chips CCs and the IF chip, vertically penetrating the respective chips including their semiconductor substrates in the respective layers. The bumps may be provided between adjacent chips in upper and lower layers. The bumps may be arranged in alignment with the TSVs in a horizontal plane. The bumps may electrically connect or couple the adjacent chips.

The TSVs of the respective chips may be aligned with one another and form TSV columns vertically extending as terminals providing connections between the chips in upper and lower layers. The TSV columns may provide the IOs between the channels of the chips. In some embodiments, in a case of a horizontal plane having an X-Y coordinate plane with an X-axis and a Y-axis perpendicular to each other, one TSV of one chip in an upper layer may have the same X-axis coordinate and Y-axis coordinate as another TSV of another chip in an adjacent lower layer. The two TSVs thus penetrate, at the same X-Y coordinates, front and back surfaces of the two chips along a vertical plane perpendicular (or substantially perpendicular within reasonable tolerances of fabrication, measurement, etc.) to the horizontal plane.

In some embodiments, the TSVs may be coupled or connected in a spiral structure. In the spiral structure, the TSVs or the terminal connections provided by the TSVs are offset in one direction in the horizontal plane from one chip in an upper layer to another chip in an adjacent lower layer. For example, in the case of the horizontal plane along the X-Y axes, the X-Y coordinates of the TSV in the upper layer are shifted from the X-Y coordinates of the TSV in the adjacent lower layer in at least one of X-Y directions. Such TSVs or terminal connections may be referred to as spiral TSVs or spiral connections.

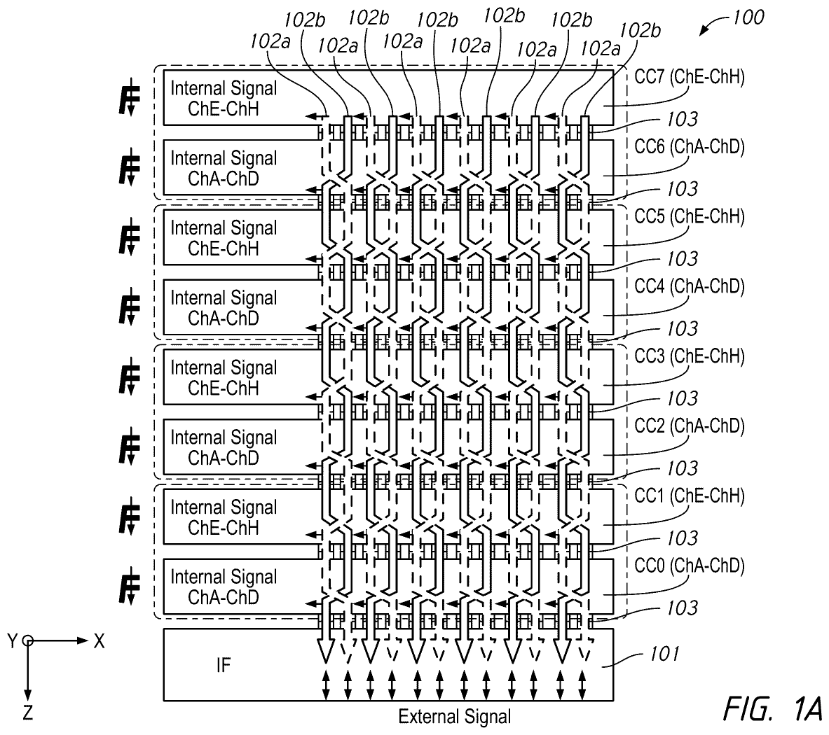

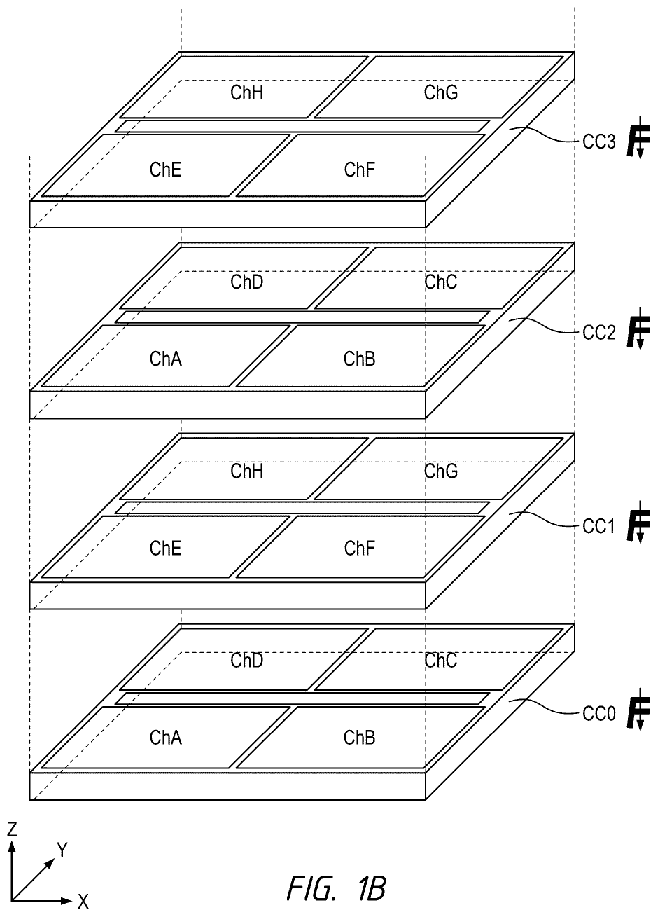

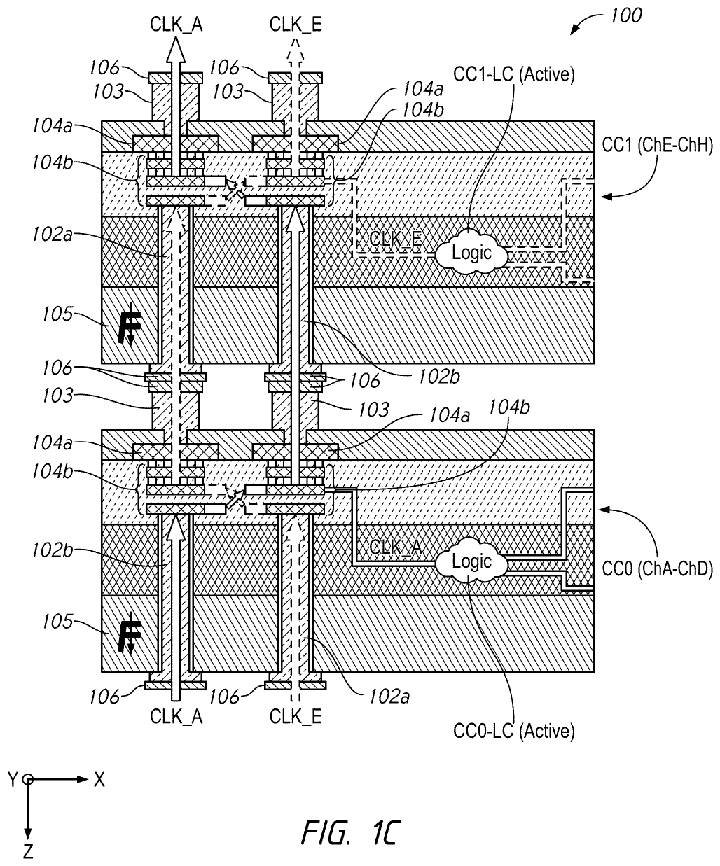

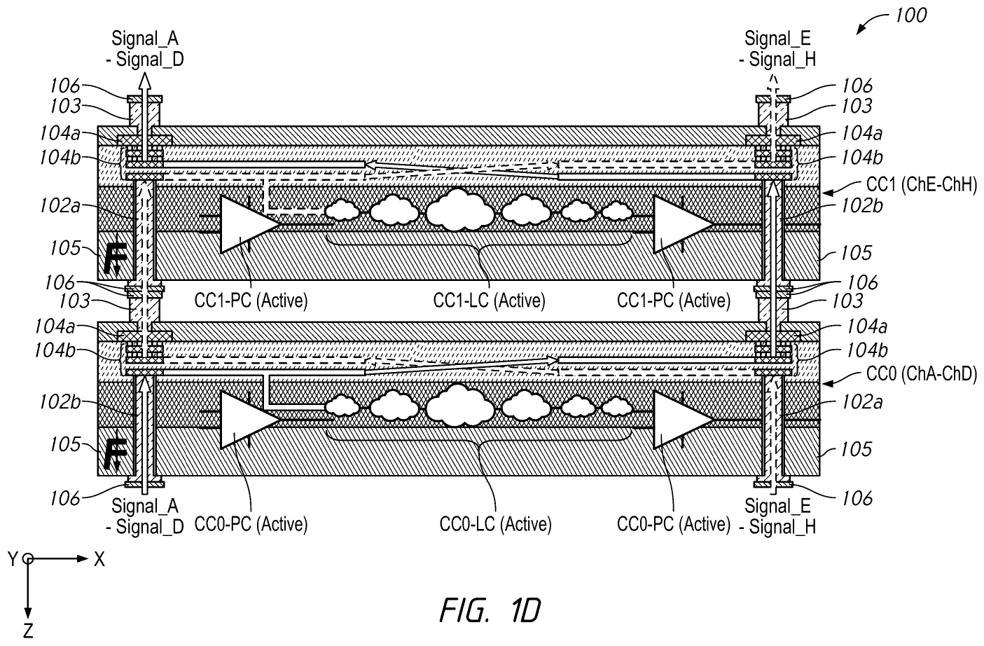

FIG. 1A schematically illustrates an example of at least part of an apparatus 100 including a plurality of core chips CCs and an IF chip 101 with a plurality of spiral TSVs 102a and 102b according to an embodiment of the disclosure. FIG. 1B schematically illustrates an example of part of a channel layout of core chip layers according to an embodiment of the disclosure. FIG. 1C schematically illustrates an example of part of core chip layers in a cross-sectional view according to an embodiment of the disclosure. FIG. 1D schematically illustrates another example of part of core chip layers in a cross-sectional view according to an embodiment of the disclosure. The apparatus 100 may be a semiconductor apparatus. The semiconductor apparatus may provide a memory device. The plurality of core chips CCs may include memory chips or memory dies each with memory arrays of a plurality of memory cells. The TSVs 102a and 102b may also be collectively referred to as TSVs 102. In the drawings, the TSVs 102a and the TSVs 102b and signals traveling through and/or corresponding to the TSVs 102a and the TSVs 102b are illustrated with dotted lines and solid lines, respectively, to distinguish from each other. In FIG. 1B, the TSVs 102 and other elements, such as the IF chip 101 and bumps 103, are omitted for ease of illustration.

The plurality of core chips CC0-CC7 are stacked on the IF chip 101 in a sequential order of CC0, CC1, CC2, and so on. The example shows eight core chips CC0-CC7. In the case of each core chip being a memory chip, there are eight memory chips stacked on one another. The number of the core chips in the stack is not limited to the present example and may be determined based on specifications, designs, etc. The core chips CC0-CC7 may also be referred to as core dies. Each of the core chips CC0-CC7 may form an individual semiconductor device, and the group of the core chips CC0-CC7 may form a stacked semiconductor device.

Each of the core chips CC0-CC7 includes a plurality of channels Chs. In the example, two adjacent core chips (e.g., CC0 and CC1, CC2 and CC3, and so on) form a pair or a set (indicated by a dashed-and-dotted line in the drawing of FIG. 1A), and a plurality of channels ChA-ChE are assigned to each pair. In the pair of the core chips CC0 and CC1, for example, the core chip CC0 in the lower layer includes four channels ChA-ChD, and the core chip CC1 in the upper layer includes four channels ChE-ChH. The four channels are arranged in matrix in a plan view or in a horizontal plane (that is an X-Y axis plane illustrated in the drawing, for example) in the corresponding layer. In the case of a memory device, in one instance, the core chip CC0 may be a 4 GB memory chip/die, the core chip CC1 may be another 4 GB memory chip/die, and the pair may provide one unit of an 8 GB memory. In another instance, the pair may provide one unit of a 16 GB memory with each of two core chips of the pair being an 8 GB memory chip/die. In the latter instance, each core chip may include eight channels. The memory size is not limited thereto and can be determined based on specifications, designs, etc. of the memory device.

Each of the core chips CC0-CC7 may include a command circuit for the assigned channels. A command signal may be independently assigned and transmitted for each channel. The command signal may include a control signal, a clock signal, and a data signal. Each of the core chips CC0-CC7 includes a plurality of wiring layers (such as metal layers) 104a and 104b provided above a semiconductor substrate 105. The wiring layers 104a and 104b are stacked and connected with one another via conductive contacts. The core chips CC0-CC7 are stacked on the IF chip 101 in a face-up manner wherein the uppermost wiring layer 104a (such as a top metal layer provided by, for example, a BEOL process) of each chip face upward. Between the respective chips are a plurality of bumps 103. The bumps 103 are aligned with the corresponding TSVs 102. The bumps 103 include a conductive material. The bumps 103 electrically connect or couple the upper and lower chips. The bumps 103 may be microbumps. The bumps 103 facing each other in a vertical direction (that is a direction along a Z axis illustrated in the drawing, for example) may be connected via conductive pads 106.

The IF chip 101 at the bottom of the chip stack structure may be coupled to an interposer IP (not separately depicted) via external terminals or balls. The IF chip 101 provides a plurality of interfaces for signals, including external signals, to and from the stacked core chips CC0-CC7 or the channels thereof. The signals are transmitted among the core chips CC0-CC7 and the IF chip 101 through the TSVs 102 of the respective chips (and also the bumps 103 between the respective chips).

The TSVs 102a and 102b or the terminal connections provided by the TSVs 102a and 102b are in the spiral structure in which the terminal connections are offset or shifted in one direction in the horizontal plane from one chip in an upper layer to another chip in a lower layer. In the example, TSV 102a may be used for the channels ChE-ChH of the corresponding core chips CCs to provide individually-assigned command signals, and TSV 102b may be used for the channels ChA-ChD of the corresponding core chips CCs to provide individually-assigned command signals. Looking from the top layer of the stacked structure, the TSV 102a, which is in a first column forming a pair with the neighboring TSV 102b, is first coupled or connected to corresponding terminals of the channels ChE-ChH at the core chip CC7 layer of the first pair. The TSV 102a then extends to the core chip CC6 layer of the same first pair, skips the channels ChA-ChD of the core chip CC6, and is shifted in the X-direction (for example, by being coupled or connected to at least one of the bumps 103 or at least one of wiring layers 104b at a neighboring position in the X-Y axis plane). The TSV 102a extends to the core chip CC5 layer in the next pair and is shifted back in the opposite X-direction (for example, by being coupled or connected to one of the bumps 103 or one of the wiring layers 104b at an original position in the X-Y axis plane) to be coupled or connected to corresponding terminals of the channels ChE-ChH of the core chip CC5. The same spiral path continues until it reaches the IF chip 101. At the neighboring position in the first column, the TSV 102b extends from the core chip CC7 layer to the core chip CC6 layer, and is shifted in the X-direction (for example, by being coupled or connected to one of the bumps 103 or one of the wiring layers 104b at a neighboring position in the X-Y axis plane) to be coupled or connected to corresponding terminals of the channels ChA-ChD of the core chip CC6. The TSV 102b then extends to the core chip CC5 layer, skips the channels ChE-ChH of the core chip CC5, and is shifted back in the opposite X-direction (for example, by being coupled or connected to one of the bumps 103 or one of the wiring layers 104b at an original position in the X-Y axis plane). The TSV 102b further extends to the core chip CC4 layer, and is shifted again in the X-direction to be coupled or connected to corresponding terminals of the channels ChA-ChD of the core chip CC4. The same spiral path continues until it reaches the IF chip 101. More specifically, referring to FIG. 1C, as in the illustrated example, the TSV 102a provides the spiral path between the core chip CC0 (ChA-ChD) and the core chip CC1 (ChE-ChE) with the appropriate wirings forming the spiral structure and provides, for example, clock signal E to a logic circuit CC1-LC in the core chip CC1 in the spiral manner. Similarly, the TSV 102b provides another spiral path between the core chip CC0 (ChA-ChD) and the core chip CC1 (ChE-ChE) with the appropriate wirings forming the spiral structure and provides, for example, clock signal A to a logic circuit CC0-LC in the core chip CC0 in the spiral manner. In the illustrated example, the spiral TSVs 102a and 102b have the wirings provided to connect at least ones of the wiring layers 104b in the X-Y plane and form the spiral structure such that the signals travel from the TSV 102a to the neighboring TSV 102b or vice versa. Such a spiral structure or a spiral connection may also be referred to as a staggered structure or a staggered connection. Also, the same spiral or staggered paths are arranged for other columns forming pairs with the other neighboring TSVs 102a and 102b. Since such paths are clearly illustrated in the drawings and the details thereof can be appreciated and understood from the above-detailed descriptions of the first column, their descriptions are omitted herein.

The channels ChA-ChD of the core chips CC0, CC2, CC4, and CC6 may not be in an active state simultaneously with one another. Similarly, the channels ChE-ChH of the core chips CC1, CC3, CC5, and CC7 may not be in an active state simultaneously with one another. For example, the channels ChA of the core chips CC0 and the core chip CC2 in the different pairs may not be active at the same time, and the channels ChE of the core chips CC1 and CC3 in the different pairs may not be active at the same time. On the other hand, the channel ChA of the core chip CC0 and the channel E of the core chip CC1 in the same pair may be simultaneously activated. Referring to FIGS. 1C and 1D, each of the core chips CC0 and CC1 may include logic circuits CC0-LC/CC1-LC and/or analog circuits (such as power supply circuits CC0-PC/CC1-PC), and all circuits may be in an active state. The same goes for the respective chip pairs. In the case of the core chips CCs being memory chips, such as DRAM chips or HBM chips, the logic circuits and the analog circuits may be provided for corresponding memory banks.

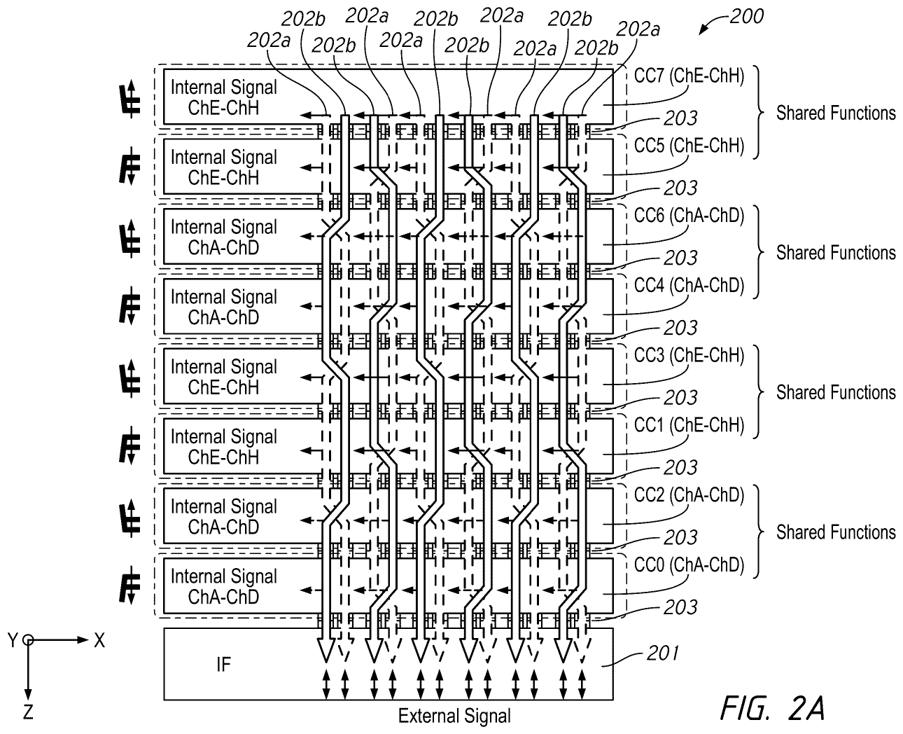

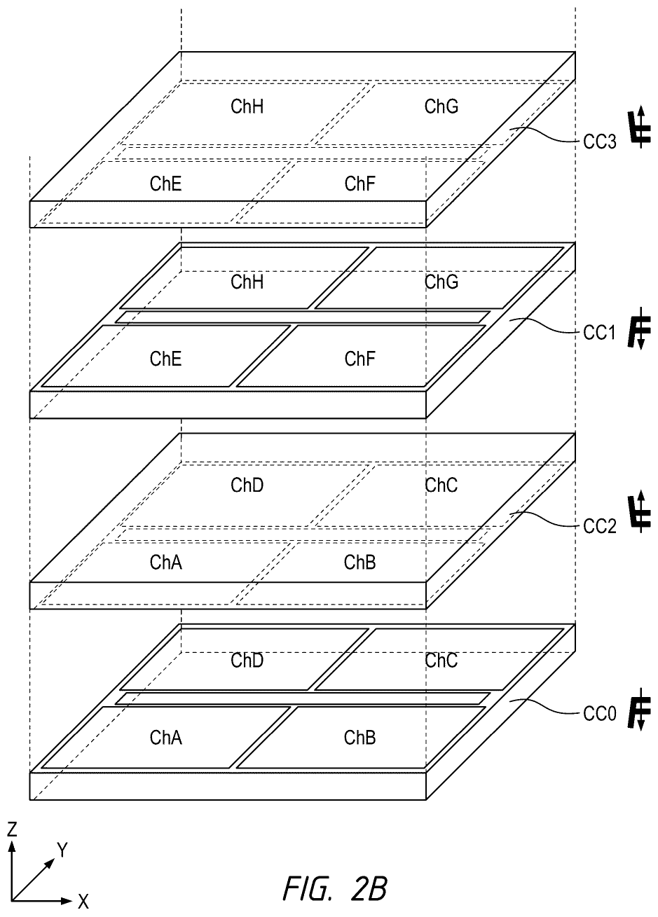

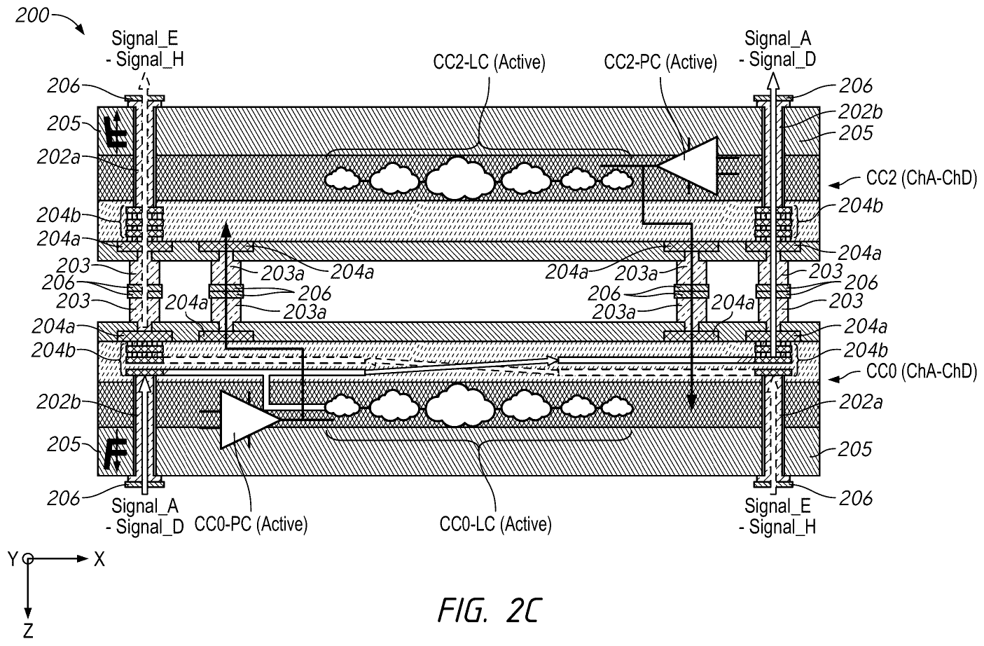

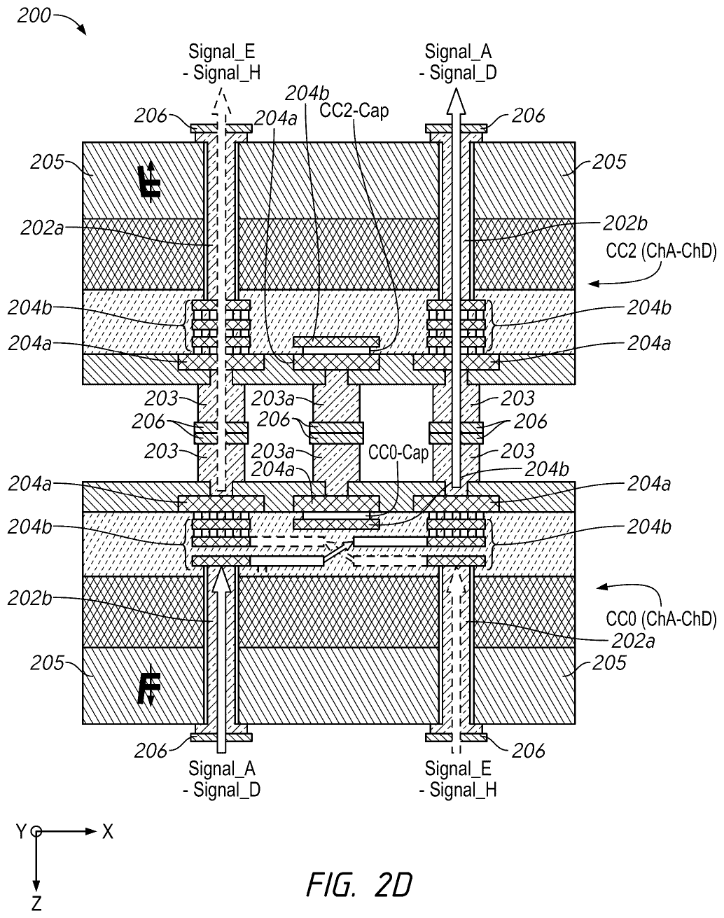

FIG. 2A schematically illustrates an example of at least part of an apparatus 200 including a plurality of core chips CCs and an IF chip 201 with a plurality of spiral TSVs 202a and 202b according to an embodiment of the disclosure. FIG. 2B schematically illustrates an example of part of a channel layout of core chip layers according to an embodiment of the disclosure. FIG. 2C schematically illustrates an example of part of core chip layers in a cross-sectional view according to an embodiment of the disclosure. FIG. 2D schematically illustrates another example of part of core chip layers in a cross-sectional view according to an embodiment of the disclosure. The apparatus 200 may be a semiconductor apparatus. The semiconductor apparatus may provide a memory device. The plurality of core chips CCs may include memory chips or memory dies each with memory arrays of a plurality of memory cells. The TSVs 202a and 202b may also be collectively referred to as TSVs 202. In the drawings, the TSVs 202a and the TSVs 202b and signals traveling through and/or corresponding to the TSVs 202a and the TSVs 202b are illustrated with dotted lines and solid lines, respectively, to distinguish from each other. In FIG. 2B, the TSVs 202 and other elements, such as the IF chip 201 and bumps 203, are omitted for case of illustration.

Unlike the sequential stacking order of the core chips CC0-CC7 in the example of FIGS. 1A and 1B, for example, the stacking order of the core chip CC1 and the core chip CC2 in the example of FIGS. 2A and 2B are reversed such that the core chip CC2 is adjacent to the core chip CC0 in the vertical direction (that is the direction along the Z axis perpendicular or substantially perpendicular to the X and Y axes as illustrated in the drawing). The channels ChA-ChD of the core chip CC0 and the channels ChA-ChD of the core chip CC2 are arranged in the same matrix pattern. The channels ChE-ChH of the core chip CC1 and the channels ChE-ChH of the core chip CC3 are arranged in the same matrix pattern. Similarly, the layer positions of the core chip CC5 and the core chip CC6 are switched such that the core chip CC6 is adjacent to the core chip CC4 and the core chip CC5 is adjacent to the core chip CC7 in the vertical direction. The channels ChA-ChD of the core chips CC4 and CC6 are in the same matrix pattern. The channels ChE-ChH of the core chips CC5 and CC7 are in the same matrix pattern. The matrix arrangements of the channels Chs in the respective core chips CCs are not limited to hereto and can be different from each other. For example, the channels ChA-ChD of the core chip CC2 may be arranged at the different positions or the different order within the matrix of the core chip CC2 from the channels ChA-ChD of the core chip CC0 such that, for example, ChA of CC2 faces ChD of CC0. Various arrangements are applicable depending on specifications, designs, and such.

Furthermore, the adjacent core chips CCs are provided in a face-to-face manner. In the example, the core chips CCs are alternately stacked in face-up and face-down manners. A first group of every other core chips is in a face-up manner, and a second group of every other core chips is in a face-down manner. For example, the core chip CC0 at the bottom of the stacked structure is provided on the IF chip 201 in a face-up manner with its uppermost wiring layer 204a (above other wiring layers 204b in FIG. 2C) facing upward and its semiconductor substrate 205 facing downward toward the IF chip 201, and the core chip CC2 is stacked in a face-down manner with its uppermost wiring layer 204a being at the bottom of its internal layer structure and facing the uppermost wiring layer 204a of the core chip CC0. The core chip CC2 has its semiconductor substrate 205 being at the top of the internal layer structure and facing the semiconductor substrate of the core chip CC1 which is in a face-up manner. The uppermost wiring layer of the core chip CC1 faces that of the core chip CC3 which is in a face-down manner. The core chips CC4 (face-up) and CC6 (face-down) and the core chips CC5 (face-up) and CC7 (face-down) are also provided in the face-to-face manner. The face-up and face-down manners may be referred to as forward and reverse direction manners or simply forward and reverse directions, respectively. The uppermost wiring layers of the respective core chips CCs facing each other are connected by the TSVs 202 (and the bumps 203, such as microbumps, arranged in alignment with the corresponding TSVs 202 between the adjacent layers). By stacking the core chips CCs in the face-to-face manner or alternately stacking the core chips CCs in the face-up and face-down manners or forward and reverse directions, the degree of freedom in where the TSVs 202 can be placed is further increased, and the degree of freedom in exchanging signals between the stacked core chips CCs is further improved. The uppermost wiring layers may be top metal wiring layers formed by, for example, back-end-of-line BEOL processes.

In a similar manner to the TSVs 102a and 102b, the TSVs 202a and 202b may be used for the channels ChE-ChH and the channels ChA-ChD of the corresponding core chips CCs, respectively. To correspond to the core chips CCs and the channels Chs arrangement of the instant example, however, the TSVs 202a and 202b provide different spiral connections from those provided by the TSVs 102a and 102b. Looking from the top layer of the stacked structure, the TSV 202a, which is in a first column forming a pair with the neighboring TSV 202b, is first coupled or connected to corresponding terminals of the channels ChE-ChH (which may be in an active state) at the core chip CC7 and CC5 layers. The TSV 202a extends to the core chip CC6 layer, is shifted in the X-direction (for example, by being coupled or connected to at least one of the bumps 203 or at least one of wiring layers 204b in a neighboring position in the X-Y plane), and further extends to the core chip CC4 layer while skipping the channels ChA-ChD (which the TSV 202a is not responsible for) of the core chips CC6 and CC4. The TSV 202a then extends to the core chip CC3 layer, is shifted back in the opposite X-direction (for example, by being coupled or connected to at least one of the bumps 203 or at least one of wiring layers 204b at an original position in the X-Y plane), and reaches CC1 while being coupled or connected to corresponding terminals of the channels ChE-ChH (which may be in an active state) of the core chips CC3 and CC1. The TSV 202a further extends to the core chip CC2 layer, is shifted again in the X-direction, and reaches the core chip CC0 layer while skipping coupling and connecting with the channels ChA-ChD of the core chips CC2 and CC0. The TSV 202a then finally reaches the IF chip 201. At the neighboring position in the same first column, the TSV 202b extends from the core chip CC7 layer and passes the core chip CC5 layer, skipping the channels ChE-ChH (which the TSV 202b is not responsible for) of the core chips CC7 and CC5. The TSV 202b reaches the core chip CC6 layer, is shifted in the X-direction, and extends to the core chip CC4 layer, while being coupled or connected to corresponding terminals of the channels ChA-ChD (which may be in an active state) of the core chips CC6 and CC4. The TSV 202b then extends and reaches the core chip CC3 layer where it is shifted back in the opposite X-direction, further extends through the core chip CC1 layer to the core chip CC2 layer where it is shifted again in the X-direction, and continues to the core chip CC0 layer. Until it reaches the core chip CC2 layer, the TSV 202b skips coupling or connection with the channels ChE-ChH (which the TSV 202b is not responsible for) of the core chips CC3 and CC1. At the core chip CC2 and CC0 layers, the TSV 202b is coupled or connected to corresponding terminals of the channels ChA-ChD (which may be in an active state) of the core chips CC2 and CC0. The TSV 202b then finally reaches the IF chip 201. The same or similar spiral (or staggered) paths are arranged for other columns forming pairs with the other neighboring TSVs 202a and 202b. Since such paths are clearly illustrated in the drawings and the details thereof can be readily appreciated and understood from the above-detailed descriptions of the first column, their descriptions are omitted herein.

In the example core chip layer structure with the spiral TSVs 202 connecting the respective chip layers CCs to provide the assigned or corresponding command signals thereto in the spiral manner, the channels ChA-ChD of one layer (e.g., the core chip CC0 layer or the core chip CC4 layer) and the channels ChA-ChD of another adjacent layer (e.g., the core chip CC2 layer or the core chip CC6 layer) may not be in an active state or in an inactive state at the same time. For example, referring to FIG. 2C, while the channels ChA-ChD (such as logic circuits CC0-LC and power supply analog circuits CC0-PC) of the core chip CC0 in the face-up manner may be in the inactive state, the channels ChA-ChD (such as logic circuits CC2-LC and power supply analog circuits CC2-PC) of the core chip CC2 in the face-down manner may be in the active state. Similarly, while the channels ChE-ChH of one layer (e.g., the core chip CC1 layer or the core chip CC5 layer) may be in the inactive state, the channels ChE-ChH of another adjacent layer (e.g., the core chip CC3 layer or the core chip CC7 layer) may be in the active state. This way, function circuits or functions provided by the channels ChA-ChD or the channels ChE-ChH of the adjacent core chips (e.g., CC0 and CC2, CC1 and CC3, CC4 and CC6, and CC5 and CC7) in the lower and upper layers may be shared through the corresponding spiral TSVs 202. Therefore, at least one common channel or at least one common function is defined in the core chips facing each other. For example, the channel ChA of the core chip CC0 may be in an inactive state where a function circuit provided thereto is not active or a function assigned thereto is not performed while the channel ChA of the core chip CC2 may be in an active state where a function circuit provided thereto is active or a function assigned thereto is performed in response to the assigned command signals provided by the corresponding spiral TSVs 202. The function circuit or the function of the channel ChA of the core chip CC2 is the same as that of the channel ChA of the core chip CC0. Similarly, the channel ChE of the core chip CC1 may be in an inactive state where a function circuit or a function thereof is not active or performed while the channel ChE of the core chip CC3 may be in an active state where a function circuit or a function thereof, which is the same as that of the channel ChE of the core chip CC1, is active or performed in response to the assigned command signals provided by the corresponding spiral TSVs 202. Still in one instance, the channels ChA-ChD of one core chip (e.g., CC2) and the channels ChA-ChD of another layer (e.g., CC6) may be activated simultaneously, and the channels ChE-ChH of one core chip (e.g., CC3) and the channels ChE-ChH of another core chip (e.g., CC7) may be activated simultaneously. Active and inactive states of the channels of the respective core chips are not limited to the described examples. Such states can be determined and switched as appropriate. Examples of the function circuits or functions include, but are not limited to, logic circuits and analog circuits. Examples of the analog circuits include, but are not limited to, power supply circuits, power generating circuits, and compensation capacitor circuits. The command signals may come from a processor, such as a memory controller, and be transmitted by the IF chip 201 to the respective core chips CCs and channels Chs via the TSVs 202 in the spiral manner. The command signals may include control signals, clock signals, data signals, or the like.

According to the present embodiment and examples, a circuit with half the full function may be necessary in each of the two adjacent core chips CCs to achieve the full function between the adjacent core chips. Referring to FIG. 2C, as one example, each of the adjacent core chips CC0 and CC2 requires half the number of the power supply circuits CC0-PC/CC2-PC if compared with the core chips CC0 and CC1 in the example of FIG. 1D. This reduces a space needed for the power supply circuits, while suppressing or mitigating resistance value fluctuations. Hence, further chip downsizing is achieved, and the overall size of the apparatus 200 is decreased.

Moreover, since the uppermost wiring layers 204a of the core chips CC0 and CC2 face each other, the flexibility of arranging terminals, such as bumps 203a, between the two chips increases. The bumps 203a are provided between the adjacent upper and lower core chips in addition to the bumps 203. The bumps 203a may be microbumps. The adjacent core chips or their uppermost wiring layers 204a are connected by the bumps 203a. The bumps 203a may be arranged at positions corresponding to or in alignment with, for example, the uppermost wiring layers 204a and/or the function circuits. The bumps 203a facing each other in the vertical direction may be connected via conductive pads 206. The power supply from the power supply chips CC0-PC and CC2-PC can therefore be further efficiently shared through such terminals provided at appropriate positions. Accordingly, the degree of freedom in arranging the power supply circuits among the stacked core chips CCs increases. The number of circuits can hence be further reduced, or at least an increase in the number of circuits can be further suppressed. The power resistance or the power supply resistance becomes further uniform in the circuits. A need for a more robust power supply network can therefore be reduced, and the core chips CCs including the power supply circuits can be further downsized.

The power supply may be shared through one or more bumps among the plurality of bumps 203a between the adjacent core chips. The power may be supplied or input to the logic circuits or other function circuits. The power supply may also be shared through one or more TSVs among the plurality of TSVs 202 between the adjacent core chips. Some signals may also be sent and received through the bumps 203a between the function circuits of the adjacent core chips. In a case where the power input or the signal input of the function circuits are not directly connected with the bumps 203 or the uppermost wiring layers 204a of the respective core chips, there may be provided one or more wirings in an appropriate manner that the power and/or the signals are input to the respective function circuits from and to the adjacent core chips. The wirings may be vertical wirings and/or a combination of vertical and horizontal wirings arranged to provide electrical paths.

Referring to FIG. 2D, as another example where compensation capacitor circuits or compensation capacitors CC0-Cap and CC2-Cap are provided in the adjacent core chips CC0 and CC2 and connected to each other by the bumps 203a (and the conductive pads 206 between the bumps 203a), compensation capacitance may be shared. If the compensation capacitors of the two core chips have the same capacitance value (Cap1) and if the core chip CC0 is inactive while the core chip CC2 is active, the total compensation capacitance is doubled (2×Cap1) for the active core chip CC0. This indicates that, for example, if the total capacitance value Cap1 is required between the adjacent core chips and even if only one of the adjacent core chips is in the active state, each of the compensation capacitors CC0-Cap and CC2-Cap which are connected to each other by the bumps 203a only needs a half of the capacitance value (Cap1/2) and can be downsized by half.

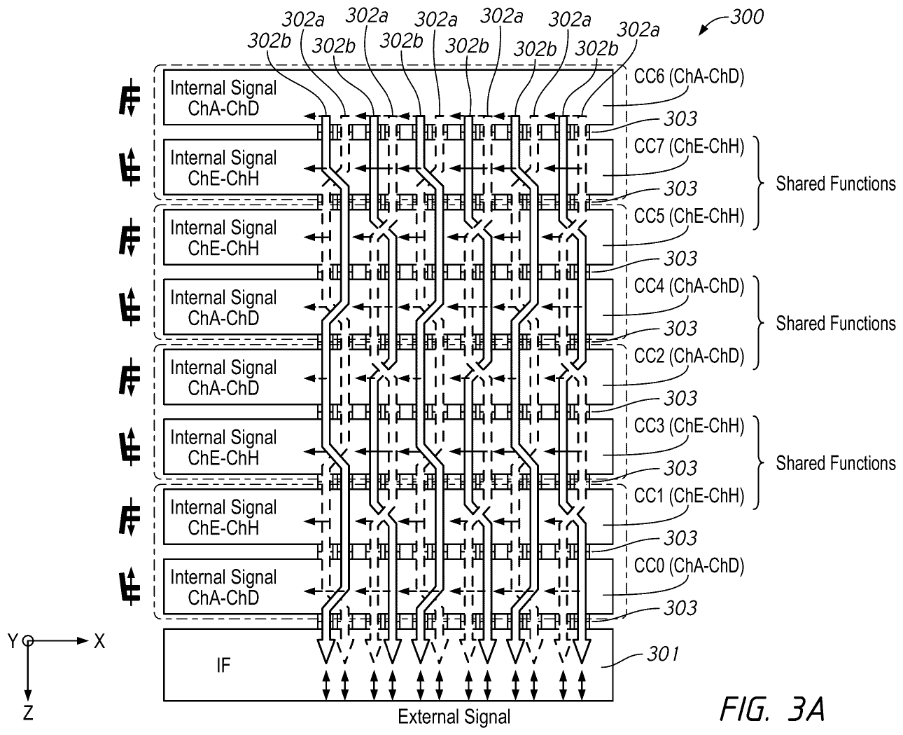

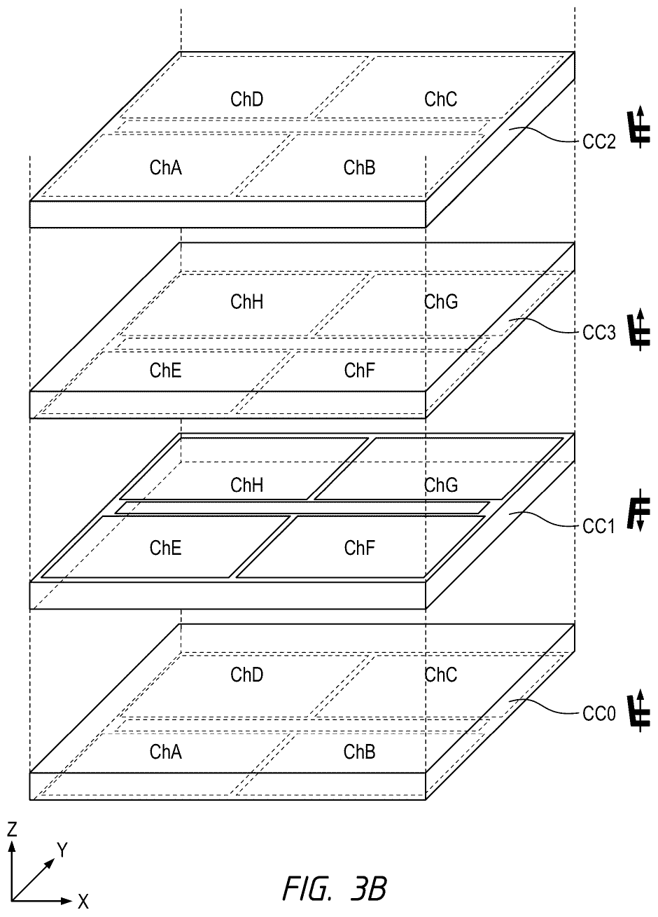

FIG. 3A schematically illustrates an example of at least part of an apparatus 300 including a plurality of core chips CCs and an IF chip 301 with a plurality of spiral TSVs 302a and 302b according to an embodiment of the disclosure. FIG. 3B schematically illustrates an example of part of a channel layout of core chip layers according to an embodiment of the disclosure. The apparatus 300 may be a semiconductor apparatus. The semiconductor apparatus may provide a memory device. The plurality of core chips CCs may include memory chips or memory dies each with memory arrays of a plurality of memory cells. The TSVs 302a and 302b may also be collectively referred to as TSVs 302. In the drawings, the TSVs 302a and the TSVs 302b and signals traveling through and/or corresponding to the TSVs 302a and the TSVs 302b are illustrated with dotted lines and solid lines, respectively, to distinguish from each other. In FIG. 3B, the TSVs 302 and other elements, such as the IF chip 301 and bumps 303, are omitted for case of illustration.

Unlike the sequential stacking order of the core chips CC0-CC7 in the example of FIGS. 1A and 1B, for example, the stacking order of the core chip CC2 and the core chip CC3 in the example of FIGS. 3A and 3B are reversed such that the core chip CC3 is adjacent to the core chip CC1 of the lower pair, and the core chip CC2 is adjacent to the core chip CC4 of the upper pair. Similarly, the core chip CC6 and the core chip CC7 of the uppermost pair of the stacked structure switch their layer positions such that the core chip CC7 is adjacent to the core chip CC5 of the lower pair.

Furthermore, the core chips CCs are provided in a face-to-face manner. In the example, the core chips CCs are alternately stacked in the face-up and face-down manners. For example, the core chip CC1 is provided in a face-up manner with its uppermost wiring layer facing the uppermost wiring layer of the core chip CC3 which is in a face-down manner. The semiconductor substrate of the core chip CC1 faces that of the core chip CC0 which is provided in a face-down manner on the IF chip 301. The core chip CC2 is provided in a face-up manner and the core chips CC4 is provided in a face-down manner with their uppermost wiring layers facing each other. The core chips CC5 (face-up) and CC7 (face-down) also faces each other. The core chip CC6 at the top of the stacked structure is facing upward with its semiconductor substrate facing the semiconductor substrate of the core chip CC7. The uppermost wiring layers of the respective core chips CCs face with one another and are connected by the TSVs 302 (and the bumps 303 arranged in alignment with the corresponding TSVs 302 between the adjacent layers). By stacking the core chips CCs in the face-to-face manner or alternately stacking the core chips CCs in the face-up and face-down manners (or the forward and reverse directions), the degree of freedom in where the TSVs 302 can be placed is further increased, and the degree of freedom in exchanging signals between the stacked core chips CCs is further improved.

In a similar manner to the TSVs 202a and 202b, the TSVs 302a and 302b may be used for the channels ChE-ChH and the channels ChA-ChD of the corresponding core chips CCs, respectively. To correspond to the core chips CCs and the channels Chs arrangement of the instant example, however, the TSVs 302a and 302b provide different spiral connections from those provided by the TSVs 202a and 202b. Looking from the top layer of the stacked structure, the TSV 302b, which is in a first column forming a pair with the adjacent TSV 302a, is first coupled or connected to corresponding terminals of the channels ChA-ChD (which may be in an active state) at the core chip CC6 layer. The TSV 302b then extends to the core chip CC7 layer and is shifted in the X-direction (for example, by being coupled or connected to at least one of the bumps 303 or at least one of metal layers (not separately depicted) at a neighboring position in the X-Y plane). The TSV 302b further extends through the core chip CC5 layer to the core chip CC4 layer, is shifted back in the opposite X-direction (for example, by being coupled or connected to at least one of the bumps 303 or at least one of metal layers (not separately depicted) at an original position in the X-Y plane), and reaches the core chip CC2 layer. Through this route, the TSV 302b skips coupling or connection with the channels ChE-ChH (which the TSV 302b is not responsible for) of the core chips CC7 and CC5 but is coupled or connected to corresponding terminals of the channels ChA-ChD (which may be in an active state) of the core chips CC4 and CC2. The TSV 302b then extends to the core chip CC3 layer, is shifted again in the X-direction, extends through the core chip CC1 layer to the lowermost core chip CC0 layer where it is couple or connected to corresponding terminals of the channels ChA-ChD. The TSV 302b is once again shifted back in the opposite X-direction and finally reaches the IF chip 301. At the neighboring position in the same first column, the TSV 302a extends from the uppermost core chip CC6 layer to the core chip CC7 layer, is shifted in the X-direction, and further extends to the core chip CC5 layer. The TSV 302a skips coupling or connection with the channels ChA-ChD (which the TSV 302a is not responsible for) of the core chip CC6, whereas the TSV 302a is coupled or connected to the channels ChE-ChH (which may be in an active state) of the core chips CC7 and CC5. The TSV 302a then further extends to the core chip CC4 layer, is shifted back in the opposite X-direction, passes the core chip CC2 layer to the core chip layer CC3, and is again shifted in the X-direction, and reaches the core chip layer CC1. Through this route, the TSV 302a skips coupling or connection with the channels ChA-ChD (which the TSV 302a is not responsible for) of the core chips CC4 and CC2 but is coupled or connected to corresponding terminals of the channels ChE-ChH (which may be in an active state) of the core chips CC3 and CC1. The TSV 302a then extends to the core chip CC0 layer where it skips coupling or connecting with the channels ChA-ChD, is shifted back in the opposite X-direction for the last time, and reaches the IF chip 301. The same or similar spiral (or staggered) paths are arranged for other columns forming pairs with the other neighboring TSVs 302a and 302b. Since such paths are clearly illustrated in the drawings and the details thereof can be readily appreciated and understood from the above-detailed descriptions of the first column, their descriptions are omitted herein.

In the example core chip layer structure with the spiral TSVs 302 connecting the respective chip layers CCs to provide the command signals thereto in the spiral manner, while the channels ChA-ChD of one layer (e.g., the core chip CC2 layer) may be in the active state, the channels ChA-ChD of another adjacent layer (e.g., the core chip CC4 layer) may be in the inactive state (or vice versa) at the same time. Similarly, while the channels ChE-ChH of one layer (e.g., the core chip CC1 layer or the core chip CC5 layer) may be in the active state, the channels ChE-ChH of another adjacent layer (e.g., the core chip CC3 layer or the core chip CC7 layer) may be in the inactive state (or vice versa) at the same time. The same function circuits or functions provided by the channels ChA-ChD or the channels ChE-ChH of the adjacent core chips (e.g., CC1 and CC3, CC2 and CC4, and CC5 and CC7) in the lower and upper layers may be shared through the spiral TSVs 302a and 302b. Therefore, at least one common channel or at least one common function is defined in the core chips facing each other. For example, the channel ChA of the core chip CC4 may be in an inactive state where a function circuit provided thereto is not active or a function assigned thereto is not performed while the channel ChA of the core chip CC2 may be in an active state where a function circuit provided thereto is active or a function assigned thereto is performed in response to the assigned command signals provided by the corresponding spiral TSVs 302. The function circuits or the functions of the Channels ChAs of the core chips CC2 and CC4 are the same. Similarly, the channel ChE of the core chip CC3 may be in an inactive state while the channel ChE of the core chip CC1 may be in an active state. Still in one instance, the channels ChA-ChD of one core chip (e.g., CC2) and the channels ChA-ChD of another layer (e.g., CC6) may be activated simultaneously, and the channels ChE-ChH of one core chip (e.g., CC1) and the channels ChE-ChH of another core chip (e.g., CC5) may be activated simultaneously. Active and inactive states of the channels of the respective core chips are not limited to the described examples. Such states can be determined and switched as appropriate. Examples of the function circuits or functions include, but are not limited to, logic circuits and analog circuits. Examples of the analog circuits include, but are not limited to, power supply circuits, power generating circuits, and compensation capacitor circuits. The command signals may come from a processor, such as a memory controller, and be transmitted by the IF chip 301 to the respective core chips CCs and channels Chs via the TSVs 302 in the spiral manner. The command signals may include control signals, clock signals, data signals, or the like.

Accordingly, a circuit with half the full function may be included in each of the two lower and upper core chips CCs to achieve the full function between the two core chips CCs. In the case of the shared power supply circuits, similarly to the case of FIG. 2C, a space needed for the power supply circuits is reduced, while resistance value fluctuations are suppressed or mitigated. Hence, further chip downsizing is achieved, and the overall size of the apparatus 300 is decreased. Moreover, the degree of freedom in arranging the power supply circuits among the stacked core chips CCs, which are connected by the TSVs 302a and 302b in the spiral manner, increases. The power supply is more flexible through arbitrary TSVs among the plurality of TSVs 302a and 302b. The number of circuits can be further reduced, or an increase in the number of circuits can be further suppressed. The power resistance or the power supply resistance becomes further uniform in the circuits. A need for a more robust power supply network can therefore be reduced, and the core chips CCs including the power supply circuits can be further downsized. In the case of the shared compensation capacitor circuits, similarly to the case of FIG. 2D, if the compensation capacitors of the two core chips have the same capacitance value Cap1 and if one of the adjacent core chips is inactive while another of the adjacent core chips is active, the total compensation capacitance is doubled (2×Cap1) for the active core chip. This indicates that, for example, if the total capacitance value Cap1 is required between the adjacent core chips and even if only one of the adjacent core chips is in the active state, each of the compensation capacitors which are connected to each other by the bumps 303 (and, for example, conductive pads provided between the bumps 303 facing each other) only needs a half of the capacitance value and can be downsized by half.

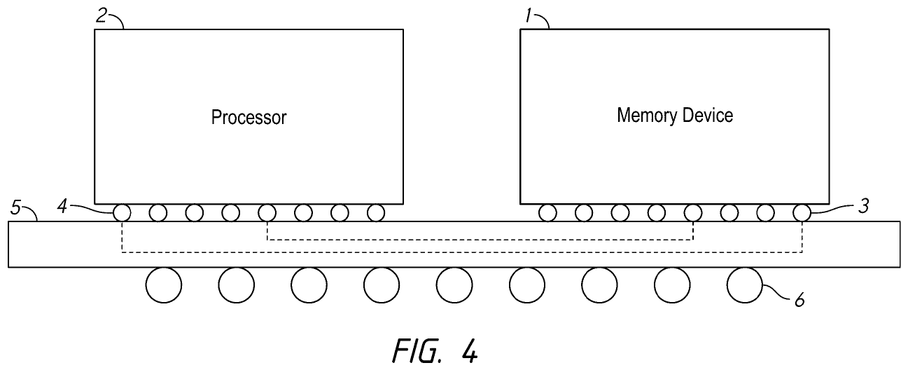

FIG. 4 is a schematic diagram of an apparatus including a memory device 1 and a processor 2 according to an embodiment of the disclosure. The memory device 1 and the processor 2 may be provided on an interposer 5. In some embodiments, a memory device may be a dynamic random access memory (DRAM). In some embodiments, the processor 2 may be a central processor, a graphical processor, or a memory controller. The memory device 1 may include terminals coupled by balls 3 (e.g., microbumps) to the interposer 5. The processor 2 may include terminals coupled by balls 4 (e.g., microbumps) to the interposer 5 and further to the corresponding terminals of the memory device 1 through the interposer 5. The interposer 5 may be stacked on a packaging substrate (not separately depicted) by balls 6 (e.g., solder balls). In some embodiments, the memory device 1 may include the apparatus 100, the apparatus 200, or the apparatus 300 described above.

In some embodiments, a memory device, such as a static random-access memory (SRAM), a flash memory, an erasable programmable read-only memory (EPROM), a magnetoresistive random-access memory (MRAM), and a phase-change memory, may be applicable. In some embodiments, a logic IC, such as a microprocessor and an application-specific integrated circuit (ASIC), may be applicable.

Although various embodiments of the disclosure have been described in detail, it will be understood by those skilled in the art that embodiments of the disclosure may extend beyond the specifically described embodiments to other alternative embodiments and/or uses and modifications and equivalents thereof. In addition, other modifications which are within the scope of the disclosure will be readily apparent to those of skill in the art based on the described embodiments. It is also contemplated that various combination or sub-combination of the specific features and aspects of the embodiments may be made and still fall within the scope of the disclosure. It should be understood that various features and aspects of the embodiments can be combined with or substituted for one another in order to form varying mode of the embodiments. Thus, it is intended that the scope of the disclosure should not be limited by the particular embodiments described above.

What is claimed is:

1. An apparatus, comprising a plurality of core chips including a plurality of spiral through-substrate vias (TSVs), wherein
the plurality of core chips are stacked with one another in a face-to-face manner to define a common channel in first and second core chips, which face each other, of the plurality of core chips,
the first core chip and the second core chip include a first function circuit and a second function circuit coupled to the first function circuit, respectively, and
the first function circuit and the second function circuit provide the same functions.

2. The apparatus according to claim 1, wherein each of the core chips includes a semiconductor substrate and a plurality of wiring layers, and uppermost wiring layers of the first and second core chips face each other.

3. The apparatus according to claim 1, wherein the first and second function circuits provide analog circuits.

4. The apparatus according to claim 3, the analog circuits include power supply circuits and/or compensation capacitor circuits.

5. The apparatus according to claim 3, wherein the first and second function circuits further provide logic circuits.

6. The apparatus according to claim 1, wherein each of the core chips includes one or more memory chips or memory dies.

7. The apparatus according to claim 1, wherein the core chips are on an interface chip coupled to an interposer.

8. The apparatus according to claim 1, further includes a plurality of bumps in alignment with the corresponding TSVs and connecting the first and second core chips.

9. The apparatus according to claim 1, wherein the first function circuit and the second function circuit are activated simultaneously responsive to a command signal provided by the spiral TSVs.

10. The apparatus according to claim 1, wherein the first core chip is in an active state, and the second core chip is in an inactive state.

11. An apparatus, comprising a plurality of core chips stacked with one another other in a face-to-face manner to provide shared functions between first and second core chips, each of the core chips including:
a plurality of wiring layers on a semiconductor substrate, uppermost wiring layers of the first and second core chips facing each other;
a plurality of channels, the channels of the first and second core chips corresponding with each other; and
a plurality of spiral through-substrate vias (TSVs) configured to provide command signals to the channels of the first and second core chips in a spiral manner, wherein
a first function circuit of the first core chip and a second function circuit of the second core chip provide the shared functions in response to the command signals provided by the spiral TSVs, the shared functions being the same with each other.

12. The apparatus according to claim 11, wherein the first and second function circuits provide analog circuits.

13. The apparatus according to claim 12, the analog circuits provide power supply circuits and/or compensation capacitor circuits.

14. The apparatus according to claim 11, wherein the first and second function circuits further provide logic circuits.

15. The apparatus according to claim 11, wherein each of the core chips includes one or more memory chips or memory dies.

16. The apparatus according to claim 11, further comprising a plurality of bumps in alignment with the TSVs and connecting the first and second core chips.

17. A memory device, comprising a plurality of memory dies including a plurality of spiral through-substrate vias (TSVs), wherein
the plurality of memory dies are stacked with one another other in a face-to-face manner to define a common channel in first and second memory dies,
the first memory die and the second memory die include a first analog circuit and a second analog circuit, respectively, and
the first analog circuit and the second analog circuit provide the same functions through the common channel in response to command signals provided by the spiral TSVs.

18. The memory device according to claim 17, wherein each of the first and second analog circuits includes a power supply circuit and/or a compensation capacitor circuit.

19. The memory device according to claim 17, wherein
each of the memory dies include a plurality of wiring layers on a semiconductor substrate,
uppermost wiring layers of the first and second memory dies face each other, and
the first and second memory dies are connected by a plurality of bumps in alignment with the TSVs.

20. The memory device according to claim 17, wherein the memory dies are on an interface chip coupled to an interposer.
